(19) United States
(12) Patent Application Publication
(10) Pub. No.: US 2025/0191991 A1
(43) Pub. Date: Jun. 12, 2025

(54) SEMICONDUCTOR PACKAGE

(71) Applicant: SAMSUNG ELECTRONICS CO., LTD., Suwon-si (KR)

(72) Inventors: Soohyun KIM, Suwon-si (KR); Younglyong KIM, Suwon-si (KR)

(73) Assignee: SAMSUNG ELECTRONICS CO., LTD., Suwon-si (KR)

(21) Appl. No.: 18/750,674

(22) Filed: Jun. 21, 2024

(30) Foreign Application Priority Data
Dec. 12, 2023 (KR) 10-2023-0179199

(51) Int. Cl. H01L 23/31; H01L 23/00; H01L 23/538; H01L 25/065

(52) U.S. Cl. CPC H01L 23/3185; H01L 23/3107; H01L 23/5385; H01L 24/16; H01L 24/32; H01L 24/73; H01L 25/0655; H01L 2224/16225; H01L 2224/26175; H01L 2224/32225; H01L 2224/73204

(57) ABSTRACT

A semiconductor package includes a package substrate, an interposer on the package substrate, electrically connected to the package substrate, a first chip structure including a first semiconductor chip, first microbumps electrically connecting the first semiconductor chip to the interposer, and a first underfill portion on the interposer and respectively covering the first microbumps, a second chip structure including a second semiconductor chip spaced apart from the first semiconductor chip, second microbumps electrically connecting the second semiconductor chip to the interposer, and a second underfill portion on the interposer and respectively covering the second microbumps, a dam structure on the interposer and surrounding at least a portion of each of the first and second underfill portions, a buffer layer on the interposer, and covering at least portions of the dam structure, the first underfill portion, and the second underfill portion, and an encapsulant covering the buffer layer.

### CROSS-REFERENCE TO RELATED APPLICATION

This application is based on and claims priority to Korean Patent Application No. 10-2023-0179199 filed on Dec. 12, 2023, in the Korean Intellectual Property Office, the entire disclosure of which is incorporated herein by reference for all purposes.

### BACKGROUND

### 1. Field

The disclosure relates to a semiconductor package.

### 2. Description of Related Art

As electronic devices are becoming ever lighter and higher performance, there is demand for the development of smaller, higher performance semiconductor chips. Microbumps may be formed to electrically connect the semiconductor chip to the substrate, and an underfill portion surrounding the microbumps may be formed to physically protect the microbumps.

### SUMMARY

Provided is a semiconductor package having improved reliability.

According to an aspect of the disclosure, a semiconductor package includes: a package substrate; an interposer on the package substrate, wherein the interposer is connected to the package substrate; a first chip structure including a first semiconductor chip on the interposer, first microbumps electrically connecting the first semiconductor chip to the interposer, and a first underfill portion on the interposer, wherein the first underfill portion covers the first microbumps; a second chip structure including a second semiconductor chip on the interposer and spaced apart from the first semiconductor chip, second microbumps connecting the second semiconductor chip to the interposer, and a second underfill portion on the interposer, wherein the second underfill portion covers the second microbumps; a dam structure on the interposer and surrounding at least a portion of each of the first and the second underfill portions; a buffer layer on the interposer, wherein the buffer layer covers at least a portion of the dam structure, the first underfill portion, and the second underfill portion; and an encapsulant on the interposer, wherein the encapsulant covers the buffer layer.

According to an aspect of the disclosure, a semiconductor package includes: a substrate; a chip structure on the substrate, the chip structure including a semiconductor chip connected to the substrate and an underfill portion sealing at least a portion of a space between the substrate and the semiconductor chip; a dam structure on an upper surface of the substrate, wherein the dam structure is arranged along at least a portion of a circumference of the underfill portion; a buffer layer, wherein the buffer layer seals the underfill portion and at least a portion of a side surface of the semiconductor chip; and an encapsulant on the substrate, wherein the encapsulant seals the buffer layer, wherein the buffer layer includes a material having an elastic modulus lower than an elastic modulus of the underfill portion and an elastic modulus of the encapsulant.

According to an aspect of the disclosure, a semiconductor package includes: a package substrate; an interposer on the package substrate; a first semiconductor chip and a second semiconductor chip, wherein the first and the second semiconductor chips are spaced apart from each other on the interposer; an underfill portion between the interposer and each of the first and the second semiconductor chips; a dam structure on the interposer and surrounding the underfill portion; a buffer layer on the interposer and covering at least a portion of respective side surfaces of the underfill portion and the first and the second semiconductor chips; and an encapsulant on the interposer and covering side surfaces of the buffer layer, wherein the dam structure includes an inner side surface in contact with the underfill portion and an outer side surface in contact with the buffer layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a cross-sectional view illustrating a semiconductor package according to one or more embodiment;

FIG. 1B is a partial enlarged view illustrating area “A” of FIG. 1A;

FIG. 1C is a plan view illustrating a section taken along line I-I′ of FIG. 1A;

FIG. 1D is a plan view illustrating a section of an alternative embodiment taken along line I-I′ of FIG. 1A;

FIG. 2A is a cross-sectional view illustrating a semiconductor package according to one or more embodiments;

FIG. 2B is a plan view illustrating a section taken along line II-II′ of FIG. 2A;

FIG. 3A is a cross-sectional view illustrating a semiconductor package according to one or more embodiments;

FIG. 3B is a plan view illustrating a cross section taken along line III-III′ of FIG. 3A;

FIG. 4A is a cross-sectional view illustrating a semiconductor package according to one or more embodiments;

FIG. 4B is a plan view illustrating a cross section taken along line IV-IV′ of FIG. 4A;

FIG. 5 is a cross-sectional view illustrating a semiconductor package according to one or more embodiments;

FIG. 6 is a cross-sectional view illustrating a semiconductor package according to one or more embodiments; and

FIGS. 7A, 7B, 7C, 7D, 7E and 7F are cross-sectional views schematically illustrating a process of manufacturing a semiconductor package according to one or more embodiments.

### DETAILED DESCRIPTION

Hereinafter, one or more embodiments will be described with reference to the accompanying drawings. Unless otherwise specified, in this specification, terms such as “top”, “upper portion”, “upper surface”, “bottom”, “lower portion”, “lower surface”, “side”, “side surface”, and the like are based on the drawings, and in reality, may vary depending on the direction in which the components are placed.

In the following description, like reference numerals refer to like elements throughout the specification.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

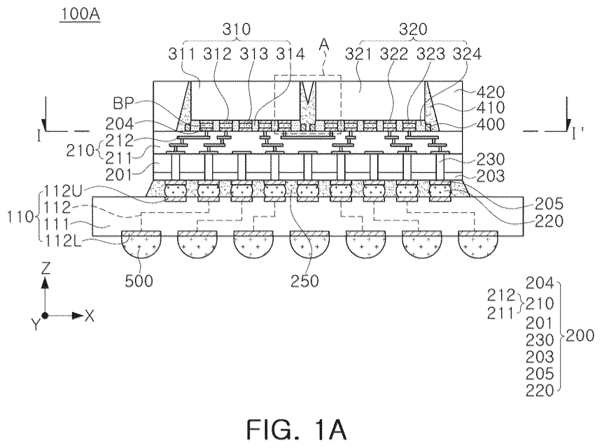

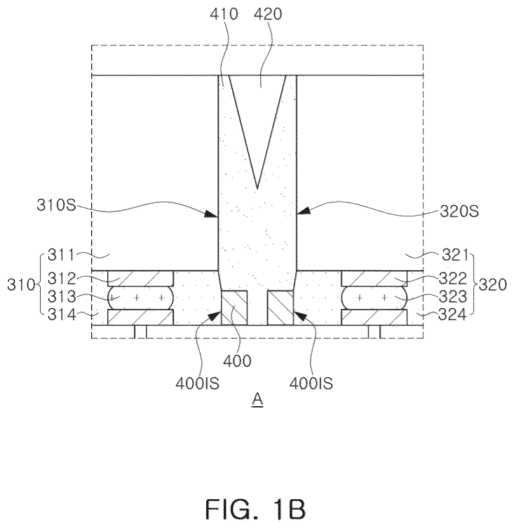

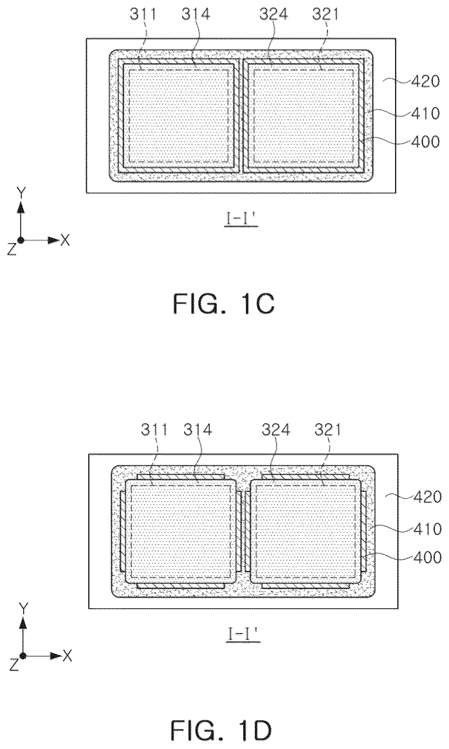

FIG. 1A is a cross-sectional view illustrating a semiconductor package according to one or more embodiments, FIG. 1B is a partially enlarged view illustrating area “A” of FIG. 1A, FIG. 1C is a plan view illustrating a section taken along line I-I′ of FIG. 1A, and FIG. 1D is a plan view illustrating a section of an alternative embodiment along line I-I′ of FIG. 1A.

Referring to FIGS. 1A to 1C, a semiconductor package 100A of an embodiment may include a package substrate 110, an interposer 200, a first chip structure 310, a second chip structure 320, a dam structure 400, a buffer layer 410, and an encapsulant 420. Referring to FIGS. 1A to 1C, the semiconductor package 100A of an embodiment may further include external connection conductors 500.

The package substrate 110 may include an insulating layer 111 and an interconnection layer 112. The package substrate 110 may further include a via structure that electrically connects the interconnection layers 112 located at different levels. The package substrate 110 may be a semiconductor package substrate including a printed circuit board (PCB), a ceramic substrate, a glass substrate, a tape wiring substrate, etc.

The insulating layer 111 may include an insulating resin. The insulating resin may include thermosetting resins such as epoxy resins, thermoplastic resins such as polyimide, or a resin in which these resins are impregnated with inorganic fillers and/or glass fibers (Glass Fiber, Glass Cloth, Glass Fabric), for example, prepreg, Ajinomoto Build-up Film (ABF), FR-4, or Bismaleimide Triazine (BT). The insulating resin may include a photosensitive resin such as Photoimageable Dielectric (PID) resin. For example, when the package substrate 110 is a PCB substrate, the insulating layer 111 may be a core insulating layer (for example, prepreg) of a copper clad laminate. The insulating layer 111 may have a large number of insulating layers stacked in the vertical direction (Z direction), and depending on the process, the boundaries between the first insulating layers at different levels may be unclear.

The interconnection layer 112 is disposed within the insulating layer 111 and may form an electrical path within the package substrate 110. The interconnection layer 112 may include at least one metal among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or alloys composed of two or more metals. The interconnection layer 112 may be a plurality of interconnection layers 112 located at different levels between the plurality of insulating layers 111. The interconnection layers 112 may include upper connection pads 112U and lower connection pads 112L. The upper connection pads 112U may be electrically connected to the interposer 200, on the insulating layer 111, and the lower connection pads 112L may be electrically connected to a plurality of external connection conductors 500, below the insulating layer 111.

The interposer 200 is disposed on the package substrate 110, and may include a semiconductor substrate 201, a lower protective layer 203, a lower pad 205, an interconnecting structure 210, a conductive bump 220, and a through-silicon via 230. The first chip structure 310 and the second chip structure 320 may be electrically connected to each other via the interposer 200.

The semiconductor substrate 201 may be formed of, for example, any one of silicon, organic, plastic, and glass substrates. When the semiconductor substrate 201 is a silicon substrate, the interposer 200 may be referred to as a silicon interposer. Unlike what is illustrated in the drawing, when the semiconductor substrate 201 is an organic substrate, the interposer 200 may be referred to as a panel interposer.

A lower protective layer 203 may be disposed on the lower surface of the semiconductor substrate 201, and a lower pad 205 may be disposed under the lower protective layer 203. The lower pad 205 may be connected to the through-silicon via 230. The interposer 200 may be electrically connected to the package substrate 110 through conductive bumps 220 disposed below the lower pad 205. The lower underfill portion 250 covers at least a portion of the conductive bumps 220 and may be disposed between the interposer 200 and the package substrate 110. The lower underfill portion 250 may include a known insulating resin such as epoxy resin.

The interconnecting structure 210 is disposed on the upper surface of the semiconductor substrate 201 and may include an interlayer insulating layer 211 and an interconnection structure 212. The interconnection structure may be a single-layer structure or multilayer structure. When the interconnecting structure 210 has a multi-layer interconnection structure, interconnection patterns of different layers may be connected to each other through contact vias. The first chip structure 310 and the second chip structure 320 may be electrically connected to the upper pad 204 through metal bumps BP (e.g., microbumps 312, 313, 322, and 323 described below).

The through-silicon via 230 may extend from the top to the bottom of the semiconductor substrate 201. Additionally, the through-silicon via 230 may extend into the interior of the interconnecting structure 210 and be electrically connected to the multilayer interconnection structure 212. In one or more embodiments, the interposer 200 may include only an interconnection structure therein and may not include the through-silicon via 230.

The interposer 200 may be used to convert or transmit an input electrical signal between the package substrate 110 and the first chip structure 310 or the second chip structure 320. Accordingly, the interposer 200 may include elements such as active elements or passive elements. Additionally, in one or more embodiments, the interconnecting structure 210 may be disposed below the through-silicon via 230. For example, the positional relationship between the interconnecting structure 210 and the through-silicon via 230 may be relative.

The first chip structure 310 is disposed on one side of the interposer 200, and may include a first semiconductor chip 311, first microbumps 312 and 313 electrically connecting the first semiconductor chip 311 and the interposer 200, and a first underfill portion 314 disposed on the interposer 200 and covering each of the first microbumps 312 and 313.

The first semiconductor chip 311 may be placed on one side of the interposer 200. The first semiconductor chip 311 contains silicon (Si), germanium (Ge), or gallium arsenide (GaAs), and various types of integrated circuits may be formed. Integrated circuits may be process chips, such as central processors (e.g., CPUs), graphics processors (e.g., GPUs), field programmable gate arrays (FPGAs), application processors (APs), digital signal processors, cryptographic processors, microprocessors, microcontrollers and the like, but are not limited thereto, and may be a logic chip such as an analog-to-digital converter or an application-specific IC (ASIC), or a memory chip such as volatile memory (for example, DRAM) or non-volatile memory (for example, ROM and flash memory). In detail, the first semiconductor chip 311 may provide a plurality of memory chips stacked in a direction perpendicular to the upper surface of the interposer 200.

The first semiconductor chip 311 is disposed on the interposer 200 and may include connection pads. The first microbumps 312 and 313 may be disposed under the first semiconductor chip 311 and spaced apart from each other at equal intervals. The first microbumps 312 and 313 may electrically connect the connection pads to the multilayer interconnection structure 212 of the interposer 200. The first microbumps 312 and 313 may include a first portion 312 in contact with the connection pads and a second portion 313 connecting the first portion 312 and the interconnection structure 212. For example, the first portion 312 may be a metal post part, and the second portion 313 may be a solder part containing a low melting point metal, but the present disclosure is not limited thereto. In one or more embodiments, the first microbumps may include only the second portion 313. Low melting point metals may include tin (Sn), indium (In), bismuth (Bi), antimony (Sb), copper (Cu), silver (Ag), zinc (Zn), lead (Pb) or alloys thereof (e.g. Sn—Ag—Cu).

The first underfill portion 314 may be disposed between the interposer 200 and the first semiconductor chip 311 to surround or cover the first microbumps 312 and 313 disposed at the bottom of the first semiconductor chip 311. The first underfill portion 314 may cover each of the first microbumps 312 and 313. The first underfill portion 314 fixes the first microbumps 312 and 313 on the interposer 200 and may physically and electrically protect the first microbumps 312 and 313. The underfill portion 314 may have a shape whose width increases from the first semiconductor chip 311 toward the upper surface of the interposer 200. On a plane, the area defined by the first underfill portion 314 may correspond to the area defined by the first semiconductor chip 311. In plan view, the first underfill portion 314 may have a shape in which the corners are curved. The first underfill portion 314 may include a known insulating resin such as epoxy resin. The first underfill portion 314 may have a capillary underfill (CUF) structure, but is not limited thereto.

The second chip structure 320 may be disposed to be spaced apart from the first chip structure 310 on the interposer 200, and may include a second semiconductor chip 321, second microbumps 322 and 323 electrically connecting the second semiconductor chip 321 and the interposer 200, and a second underfill portion 324 disposed on the interposer 200 and covering each of the second microbumps 322 and 323.

The second semiconductor chip 321 may be disposed to be spaced apart from the first semiconductor chip 311 on the interposer 200. The second semiconductor chip 321 may be a logic chip, but is not limited thereto. Since the second microbumps 322 and 323 and the second underfill portion 324 have the same or similar characteristics as the first microbumps 312 and 313 and the first underfill portion 314, the description of the second microbumps 322 and 323 and the second underfill portion 324 are essentially the same as the description of the first microbumps 312 and 313 and the first underfill portion 314 described above and thus will not be repeated.

The dam structure 400 may be disposed on the interposer 200 to surround or cover at least a portion of each of the first underfill portion 314 and the second underfill portion 324. Specifically, the dam structure 400 may be disposed along at least a portion of the circumference of the first underfill portion 314 and the second underfill portion 324. The dam structure 400 may be disposed along the outside of the area defined by the first underfill portion 314 and the second underfill portion 324. In one or more embodiments, the arrangement relationship of the dam structure 400 with respect to the area may vary. Referring to FIG. 1D, the dam structure 400 may not be disposed at portions of corners of the first underfill portion 314 and the second underfill portion 324. The dam structure 400 may provide a plurality of dam structures disposed in parallel to respective edges of the first underfill portion 314 and the second underfill portion 324. In the area defined by the first underfill portion 314 and the second underfill portion 324, the inner surface of the dam structure 400 may be in contact with the first underfill portion 314 and the second underfill portion 324. The outer surface of the dam structure 400 may be in contact with the buffer layer 410. At least a portion of the upper surface of the dam structure 400 may be in contact with the buffer layer 410, but is not limited thereto. In an embodiment, a portion of the upper surface of the dam structure 400 may be in contact with the first underfill portion 314 or the second underfill portion 324, and another portion of the upper surface of the dam structure 400 may be in contact with the buffer layer 410, but the present disclosure is not limited thereto. The horizontal distance from the inner surface 400IS of the dam structure 400 to the side surface 310S of the first semiconductor chip 311 may be about 10 μm or more and 250 μm or less, about 25 μm or more and 280 μm or less, or about 30 μm or more and 300 μm or less, but the disclosure is not limited to these ranges.

The buffer layer 410 may cover at least a portion of each of the dam structure 400, the first underfill portion 314, and the second underfill portion 324 on the interposer 200. The buffer layer 410 may cover at least a portion of the side surfaces of the first semiconductor chip 311 and the second semiconductor chip 321, respectively. The buffer layer 410 may have an inclined side shape whose width in the horizontal direction (for example, X-axis direction) becomes wider toward the upper surface of the interposer 200. The buffer layer 410 may be disposed to cover all inclined sides of the first underfill portion 314 and the second underfill portion 324, so that the first underfill portion 314 and the second underfill portion 324 are not exposed from the dam structure 400, the first semiconductor chip 311, and the second semiconductor chip 321. On a plane, the buffer layer 410 may have a shape in which the corners are curved.

The buffer layer 410 may be disposed in a space spaced apart from the first semiconductor chip 311 and the second semiconductor chip 321. In the space, the buffer layer 410 may have an inclined side extending from an uppermost end of the first semiconductor chip 311 and the second semiconductor chip 321, and the side surfaces may be connected at points spaced apart from the first semiconductor chip 311 and the second semiconductor chip 321 by the same distance.

The buffer layer 410 may include an insulating resin such as epoxy resin. The buffer layer 410 may have a capillary underfill (CUF) structure, but is not limited thereto. The buffer layer 410 may include a material with a lower elastic modulus than the first underfill portion 314 and the second underfill portion 324. The elastic modulus of each of the first underfill portion 314 and the second underfill portion 324 at room temperature may be about 5 GPa or more and 20 GPa or less, about 6 GPa or more and 15 GPa or less, or about 7 GPa or more and 13 GPa or less, but the disclosure is not limited thereto. The elastic modulus of the buffer layer 410 may be less than about 7 GPa or less than about 5 GPa, but is not limited thereto. In the present disclosure, by introducing a first underfill portion 314 and a second underfill portion 324 disposed below each of the first semiconductor chip 311 and the second semiconductor chip 321, and a buffer layer 410 disposed between the encapsulants 420 and made of a material with a relatively low elastic modulus, cracks may be prevented from occurring in the first underfill portion 314 and the second underfill portion 324 during a process in which heat is applied.

The encapsulant 420 may cover the buffer layer 410 on the interposer 200. In one or more embodiments, the encapsulant 420 may contact at least a portion of each of the first semiconductor chip 311 and the second semiconductor chip 321. The uppermost end of the encapsulant 420 may be located at the same level as the uppermost end of each of the buffer layer 410, the first semiconductor chip 311, and the second semiconductor chip 321, but is not limited thereto. The encapsulant 420 may include an insulating resin, such as a thermosetting resin such as epoxy resin, a thermoplastic resin such as polyimide, or prepreg, ABF, FR-4, BT, or Epoxy Molding Compound (EMC). For example, the encapsulant 420 may include filler dispersed in an insulating resin. The encapsulant 420 may include a material with a higher elastic modulus than the buffer layer 410, and the encapsulant 420 may include a material with a higher elastic modulus than the first underfill portion 314 and the second underfill portion 324. The elastic modulus of the encapsulant 420 may be about 10 GPa or more and 30 GPa or less, about 12 GPa or more and 25 GPa or less, or about 14 GPa or more and 22 GPa or less, but is not limited thereto.

The external connection conductors 500 may be disposed below the package substrate 110 and electrically connected to the interconnection layer 112. External connection conductors 500 may physically and/or electrically connect the semiconductor package 100A to an external device. The external connection conductors 500 may include a conductive material and may have a ball, pin or lead shape. For example, the external connection conductors 500 may be solder balls.

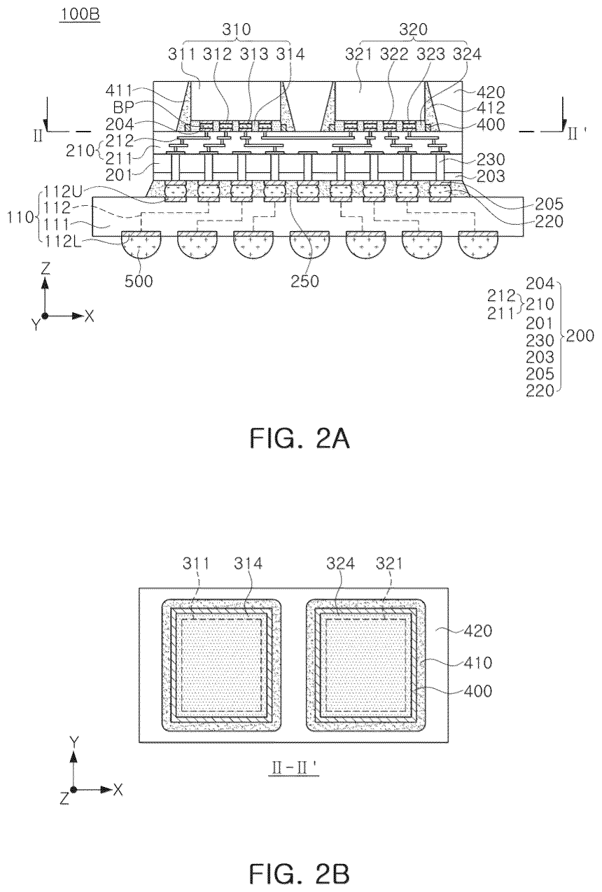

FIG. 2A is a cross-sectional view illustrating a semiconductor package 100B according to one or more embodiments, and FIG. 2B is a plan view illustrating a section taken along line II-II′ in FIG. 2A.

Referring to FIGS. 2A and 2B, the semiconductor package 100B of an embodiment may have the same or similar features as those described with reference to FIGS. 1A to 1D, except that the first chip structure 310 and the second chip structure 320 are disposed to be spaced apart from each other. The first chip structure 310 and the second chip structure 320 may be disposed on the interposer 200 to be spaced apart from each other in the horizontal direction (for example, X-axis direction). The first buffer layer 411 and the second buffer layer 412 may cover the first chip structure 310 and the second chip structure 320, respectively. The first buffer layer 411 and the second buffer layer 412 may be disposed on the interposer 200 to be spaced apart from each other in the horizontal direction. In the space between the first semiconductor chip 311 and the second semiconductor chip 321, the encapsulant 420 may contact the upper surface of the interposer 200.

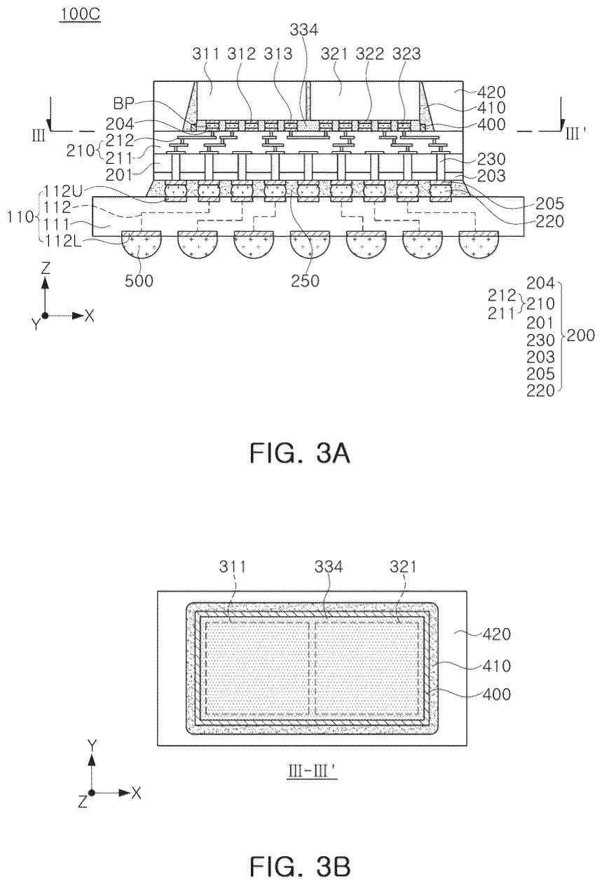

FIG. 3A is a cross-sectional view illustrating a semiconductor package 100C according to one or more embodiments, and FIG. 3B is a plan view illustrating a cut along line III-III′ of FIG. 3A.

Referring to FIGS. 3A and 3B, the semiconductor package 100C of an embodiment may have the same or similar features as those described with reference to FIGS. 1A to 2B, except that the first underfill portion 314 and the second underfill portion 324 are combined in a form 334. The first semiconductor chip 311 and the second semiconductor chip 321 may be disposed adjacent to each other on the interposer 200. The first underfill portion 314 may cover the first microbumps 312 and 313 between the first semiconductor chip 311 and the interposer 200, and the second underfill portion 324 may cover the second microbumps 322 and 323 between the second semiconductor chip 321 and the interposer 200. In the semiconductor package of an embodiment, the dam structure 400 may not be disposed in some areas between the first semiconductor chip 311 and the second semiconductor chip 321, and the first underfill portion 314 and the second underfill portion 324 may be connected to each other between the first semiconductor chip 311 and the second semiconductor chip 321. The distance between the first semiconductor chip 311 and the second semiconductor chip 321 may be in the range of about 150 μm or less, about 120 μm or less, and about 70 μm or less, but is not limited thereto. The buffer layer 410 may cover the form 334 in which the first underfill portion 314 and the second underfill portion 324 are connected to each other. The buffer layer 410 may fill the space between the first semiconductor chip 311 and the second semiconductor chip 321, and in the space, the encapsulant 420 may not overlap the buffer layer 410 in the vertical direction (for example, Z-axis direction).

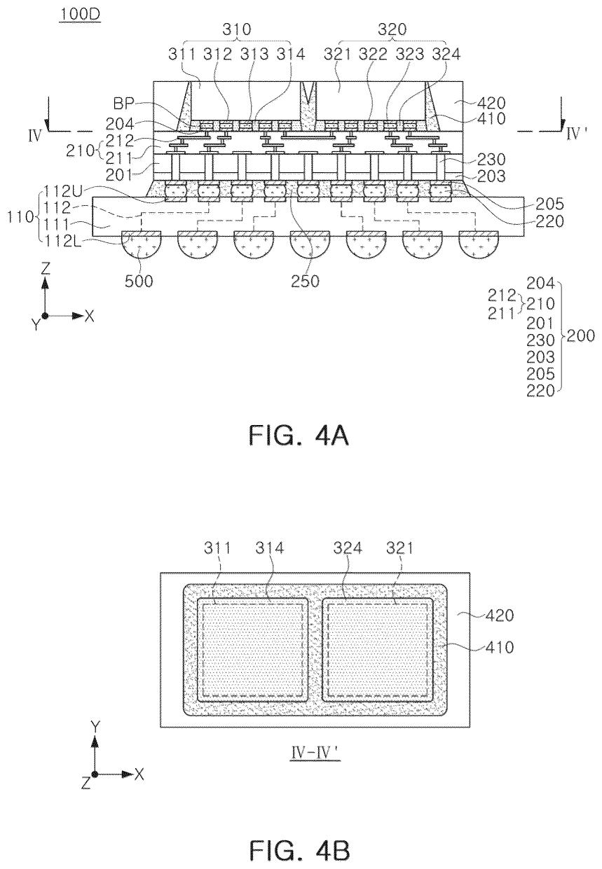

FIG. 4A is a cross-sectional view illustrating a semiconductor package 100D according to one or more embodiments, and FIG. 4B is a plan view illustrating a section taken along line IV-IV′ of FIG. 4A.

Referring to FIGS. 4A and 4B, the semiconductor package 100D of an embodiment may have the same or similar features as those described with reference to FIGS. 1A to 3B, except that the dam structure 400 is not disposed on the interposer 200. Each side of the first underfill portion 314 and the second underfill portion 324 may be in direct contact with the buffer layer 410. The first underfill portion 314 and the second underfill portion 324 may have rounded corners in a plan view. The areas of the first underfill portion 314 and the second underfill portion 324 in the semiconductor package 100D of this embodiment may be larger than the areas of the first underfill portion 314 and the second underfill portion 324 in the semiconductor package 100A of another embodiment.

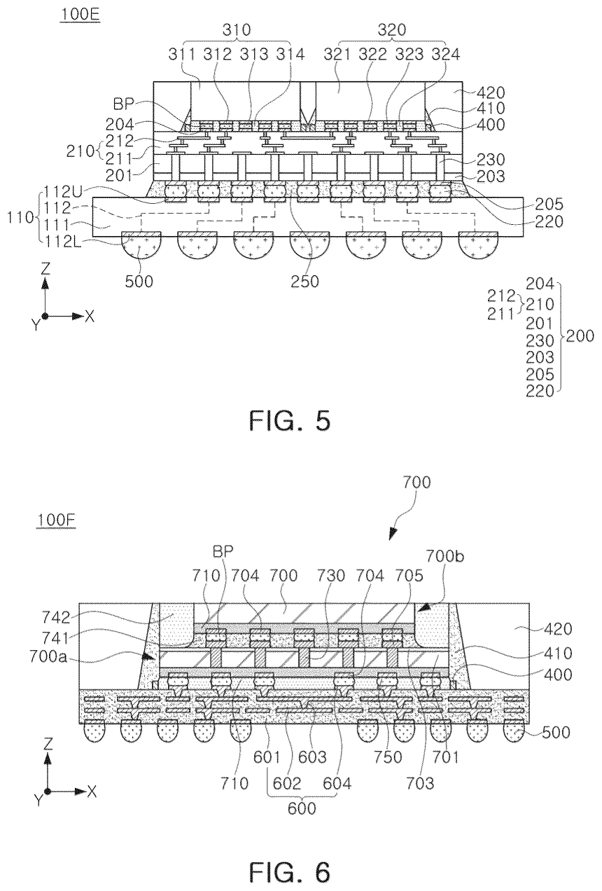

FIG. 5 is a cross-sectional view illustrating a semiconductor package 100E according to one or more embodiments.

Referring to FIG. 5, the semiconductor package 100E of an embodiment may have the same or similar features as those described with reference to FIGS. 1A to 4B, except that the height of the buffer layer 410 is lowered and the encapsulant 420 is in contact with at least a portion of the side surface of each of the first semiconductor chip 311 and the second semiconductor chip 321. The uppermost end of the buffer layer 410 may be located at a lower level than the uppermost end of the first semiconductor chip 311 and the second semiconductor chip 321. The buffer layer 410 may cover the first underfill portion 314 and the second underfill portion 324. The buffer layer 410 may cover at least a portion of the dam structure 400. The encapsulant 420 may contact at least a portion of the side surfaces of the first semiconductor chip 311 and the second semiconductor chip 321, respectively.

FIG. 6 is a cross-sectional view illustrating a semiconductor package 100F according to one or more embodiments.

Referring to FIG. 6, the semiconductor package 100F of an embodiment may have the same or similar features as those described with reference to FIGS. 1A to 5, except that one chip structure 700 is disposed on the substrate 600.

The substrate 600 is a support substrate on which the chip structure 700 is mounted and may include an insulating layer 601, redistribution layers 602, redistribution vias 603, and upper connection pads 604. The insulating layer 601 may be formed to surround or cover at least a portion of the redistribution layers 602. The insulating layer 601 may include a plurality of layers stacked in the vertical direction (Z-axis direction). Depending on the process, the boundaries between multiple layers may be unclear. The insulating layer 601 may include an insulating resin. The insulating resin may include thermosetting resin such as epoxy resin, thermoplastic resin such as polyimide, or resins impregnated with inorganic fillers, or the like, such as prepreg, Ajinomoto Build-up Film (ABF), FR-4, BT, or the like. For example, the insulating layer 601 may include a photosensitive resin such as Photo-Imageable Dielectric (PID). The redistribution layers 602 may include a plurality of redistribution layers disposed at different levels. The redistribution layers 602 may include a metal material including, for example, copper (Cu), aluminum (Al), silver (Ag), tin (Sn), gold (Au), nickel (Ni), lead (Pb), titanium (Ti), or alloys thereof. The redistribution layers 602 may include a ground pattern, a power pattern, and a signal pattern. The redistribution via 603 may penetrate a portion of the insulating layer 601 and be electrically connected to the redistribution layers 602. For example, the redistribution via 603 may interconnect redistribution layers 602 at different levels. The substrate 600 may be electrically connected to the chip structure 700 through the upper connection pads 604 and connectors 750 (where the connectors 750 may be similar to the microbumps 313 and 323 described above).

The chip structure 700 of an embodiment may include a plurality of semiconductor chips 700a and 700b stacked vertically (for example, in the Z-axis direction). At least some of the semicondutor chips (for example, “700a”), among the plurality of semiconductor chips 700a and 700b, may include through vias 730 that electrically connect the plurality of semiconductor chips 700a and 700b to each other. The chip structure 700 includes a lower semiconductor chip 700a and an upper semiconductor chip 700b, the lower semiconductor chip 700a includes a processor circuit, and the upper semiconductor chip 700b may include at least one of an input/output circuit for a processor circuit, an analog circuit, a memory circuit, and a serial-to-parallel conversion circuit. A plurality of semiconductor chips 700a and 700b may be provided in larger numbers than illustrated in the drawing. In one or more embodiments, the chip structure 700 may further include a sealing member 742 that covers at least a portion of each of the lower semiconductor chip 700a and the upper semiconductor chip 700b. In one or more embodiments, an underfill portion 741 may be formed between the lower semiconductor chip 700a and the upper semiconductor chip 700b. The lower semiconductor chip 700a and the upper semiconductor chip 700b may include a substrate 701, an upper protective layer 703, an upper pad 705, a lower pad 704, and/or a through via 730. The dam structure 400 may be disposed along at least a portion of the circumference of the underfill portion 710 disposed below the lower semiconductor chip 700a, and the buffer layer 410 may cover at least a portion of each of the dam structure 400 and the underfill portion 710. In one or more embodiments, the buffer layer 410 may contact the sealing member 742 surrounding the upper semiconductor chip 700b from the side. The buffer layer 410 may prevent cracks in the underfill portion 710 and is disposed between the sealing member 742 and the encapsulant 420, and adhesion between each of the sealing member 742 (also referred to as a suture member) and the encapsulant 420 may be strengthened.

In one or more embodiments, the chip structure 700 may include a lower semiconductor chip 700a and a plurality of upper semiconductor chips 700b stacked vertically on the lower semiconductor chip 700a, and the lower semiconductor chip 700a may be a logic chip containing, for example, central processor (CPU), graphics processor (GPU), field programmable gate array (FPGA), application processor (AP), digital signal processor (DSP), cryptographic processor, microprocessor, microcontroller, analog-to-digital converters, application-specific semiconductors (ASICs), and the like. The upper semiconductor chip 700b may be a memory chip including volatile memory, such as dynamic RAM (DRAM), static RAM (SRAM), and/or non-volatile memory, such as phase change RAM (PRAM), magnetic RAM (MRAM), resistive RAM (RRAM), and flash memory devices. The chip structure 700 may be applied to the first chip structure 310 in the semiconductor packages 100A, 100B, 100C, 100D, and 100E according to various embodiments.

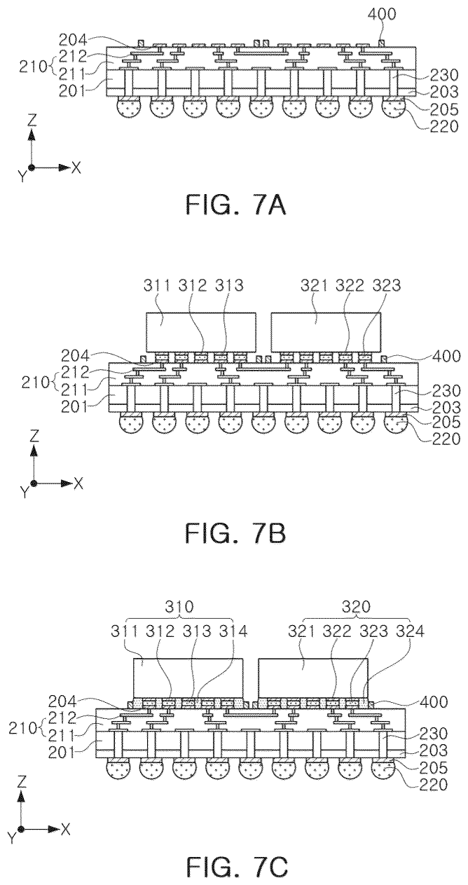

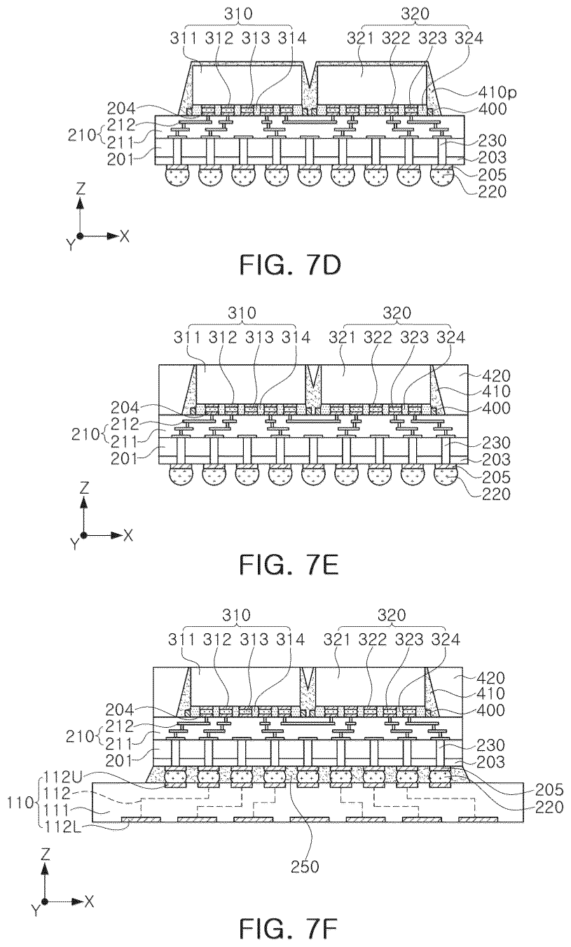

FIGS. 7A through 7F are cross-sectional views schematically illustrating the manufacturing process of a semiconductor package according to one or more embodiments.

Referring to FIG. 7A, an interposer 200 may be prepared, and the dam structure 400 may be formed on the upper surface of the interposer 200. The upper pads 204 may be disposed to be spaced apart from each other on the interlayer insulating layer 211. The upper pads 204 may be electrically connected to the multilayer interconnection structure 212. The upper pads 204 may be disposed in an area defined by the first semiconductor chip 311 and the second semiconductor chip 321. The dam structure 400 may be formed by forming a seed layer on the upper surface of the interposer 200 and then performing a plating process on the seed layer. The dam structure 400 may be disposed to be spaced apart from the upper pads 204 on the interlayer insulating layer 211. The dam structure 400 may be disposed in various ways according to the above-described embodiments, but is not limited thereto. In one or more embodiments, the dam structure 400 may not be disposed. A dam structure 400 may be disposed along at least a portion of the perimeter of the area defined by upper pads 204.

Referring to FIG. 7B, a first semiconductor chip 311 and a second semiconductor chip 321 may be attached to the interposer 200. Connection pads of the first semiconductor chip 311 may be connected through first microbumps 312 and 313 disposed therebetween. The first semiconductor chip 311 may be connected to the interconnection structure 212 of the interposer 200 through the first microbumps 312 and 313 and the upper pads 204 connected below each of the first microbumps 312 and 313. Since the second semiconductor chip 321 and the second microbumps 322 and 323 have the same or similar characteristics as the first semiconductor chip 311 and the first microbumps 312 and 313, the description of the second semiconductor chip 321 and the second microbumps 322 and 323 may be replaced with the description of the first semiconductor chip and the first microbumps 312 and 313 described above. The first semiconductor chip 311 and the second semiconductor chip 321 may be connected to the interconnection structure 212 of the interposer 200 through first microbumps 312 and 313 and second microbumps 322 and 323, respectively, and the first semiconductor chip 311 and the second semiconductor chip 321 may be electrically connected to each other via the interposer 200.

Referring to FIG. 7C, below the first semiconductor chip 311 and the second semiconductor chip 321, a first underfill portion 314 and a second underfill portion 324 may be formed surrounding and/or covering the first microbumps 312 and 313 and the second microbumps 322 and 323, respectively. The first underfill portion 314 may be formed through a process of filling the area defined by the dam structure 400 surrounding and/or covering the first microbumps 312 and 313 with a material and then curing the material. The dam structure 400 may play a role in controlling the area of the area where the first underfill portion 314 is formed. The first underfill portion 314 may be formed to contact the inner surface of the dam structure 400 within an area defined by the dam structure 400. In one or more embodiments, when the dam structure 400 is not disposed, the area of the area where the first underfill portion 314 is formed may be adjusted by adjusting the amount of filling insulating material. When the insulating material is filled without the dam structure 400, the flow speed thereof is relatively low near the corners in the area, and thus the first underfill portion 314 may be formed with rounded corners. Since the second underfill portion 324 has the same or similar characteristics as the first underfill portion 314, the description of the process for forming the second underfill portion 324 may be replaced with the description of the process for forming the first underfill portion 314 described above.

Referring to FIG. 7D, a preliminary buffer layer 410p may be formed on the interposer 200 to cover at least a portion of each of the first chip structure 310 and the second chip structure 320. After filling an insulating material to cover at least a portion of each of the first chip structure 310 and the second chip structure 320, a preliminary buffer layer 410p may be formed through a process of curing the insulating material. The material forming the preliminary buffer layer 410p may have a lower elastic modulus than the material forming the first underfill portion 314 and the second underfill portion 324. The preliminary buffer layer 410p may be formed in the space between the first semiconductor chip 311 and the second semiconductor chip 321. Within the space, the upper surface level of the preliminary buffer layer 410p may have a V- or U-shape that decreases toward the center. The preliminary buffer layer 410p may cover the side surfaces of the first underfill portion 314 and the second underfill portion 324 so that the first underfill portion 314 and the second underfill portion 324 are not exposed to the outside. The preliminary buffer layer 410p may be in contact with the outer surface of the dam structure 400. The preliminary buffer layer 410p may cover at least a portion of the upper surfaces of each of the first semiconductor chip 311 and the second semiconductor chip 321.

Referring to FIG. 7E, an encapsulant 420 may be formed on the interposer 200. After filling the interposer 200 with a sealing material, the sealing material may be cured to form the sealing material 420 (i.e., encapsulant 420). The encapsulant 420 may cover at least a portion of each of the interposer 200 and the preliminary buffer layer 410p (see FIG. 7D), and in one or more embodiments, at least a portion of each of the first semiconductor chip 311 and the second semiconductor chip 321 may be covered. The encapsulant 420 may be formed, for example, by applying and curing EMC. The upper portion of the encapsulant 420 may be flattened by polishing equipment. The planarization process may include a grinding process, Chemical Mechanical Polishing (CMP) process, or the like. The upper surfaces of each of the first chip structure 310 and the second chip structure 320 may be exposed to the upper surface of the encapsulant 420. Through the planarization process, the upper surface of the preliminary buffer layer 410p may be planarized to form the buffer layer 410.

Referring to FIG. 7F, the interposer 200 may be attached to the package substrate 110. Each of the conductive bumps 220 disposed on the lower end of the interposer 200 may be attached to the upper connection pads 112U of the corresponding package substrate 110. The interposer 200 may be electrically connected to the package substrate 110, and the first semiconductor chip 311 and the second semiconductor chip 321 may be electrically connected to the package substrate 110 through the interposer 200. A lower underfill portion 250 may be formed between the package substrate 110 and the interposer 200 to cover at least a portion of the conductive bumps 220. The lower underfill portion 250 may contain a known insulating resin, etc., and may be formed by the same or similar process as the first underfill portion 314 and the second underfill portion 324.

Referring to FIGS. 1A and 1B, the semiconductor package 100A of this embodiment may be formed by placing external connection conductors 500 under the package substrate 110. External connection conductors 500 may be attached to the insulating layer 111.

As set forth above, according to one or more embodiments, a semiconductor package having improved reliability may be provided by introducing a buffer layer disposed between an underfill portion on a lower portion of a semiconductor chip and an encapsulant.

While example embodiments have been illustrated and described above, it will be apparent to those skilled in the art that modifications and variations could be made without departing from the scope of the present disclosure as defined by the appended claims.

What is claimed is:

1. A semiconductor package comprising:
a package substrate;
an interposer on the package substrate, wherein the interposer is connected to the package substrate;
a first chip structure comprising a first semiconductor chip on the interposer, first microbumps electrically connecting the first semiconductor chip to the interposer, and a first underfill portion on the interposer, wherein the first underfill portion covers the first microbumps;
a second chip structure comprising a second semiconductor chip on the interposer and spaced apart from the first semiconductor chip, second microbumps connecting the second semiconductor chip to the interposer, and a second underfill portion on the interposer, wherein the second underfill portion covers the second microbumps;
a dam structure on the interposer and surrounding at least a portion of each of the first and the second underfill portions;
a buffer layer on the interposer, wherein the buffer layer covers at least a portion of the dam structure, the first underfill portion, and the second underfill portion; and
an encapsulant on the interposer, wherein the encapsulant covers the buffer layer.

2. The semiconductor package of claim 1, wherein the first and the second underfill portions are connected to each other.

3. The semiconductor package of claim 1, wherein the dam structure comprises a plurality of dam structures each arranged in parallel to a respective edge of the first or the second underfill portions.

4. The semiconductor package of claim 1,
wherein the first semiconductor chip comprises a memory chip, and
wherein the second semiconductor chip comprises a logic chip.

5. The semiconductor package of claim 4, wherein the first semiconductor chip comprises a plurality of memory chips including the memory chip, and wherein the plurality of memory chips are stacked in a vertical direction.

6. The semiconductor package of claim 1, wherein an elastic modulus of the buffer layer is lower than an elastic modulus of the first underfill portion and an elastic modulus of the second underfill portion.

7. The semiconductor package of claim 1, wherein an elastic modulus of the encapsulant is higher than an elastic modulus of the buffer layer.

8. The semiconductor package of claim 1, wherein an elastic modulus of the encapsulant is higher than an elastic modulus of the first underfill portion and an elastic modulus of the second underfill portion.

9. The semiconductor package of claim 1, further comprising an outer dam structure on an upper surface of the interposer, wherein the outer dam structure surrounds at least a portion of the buffer layer.

10. The semiconductor package of claim 1, wherein an upper surface of the interposer is in contact with the encapsulant in a space between the first and the second semiconductor chips.

11. The semiconductor package of claim 1, wherein the buffer layer comprises a first buffer layer covering the first underfill portion and a second buffer layer covering the second underfill portion.

12. The semiconductor package of claim 1, wherein an upper surface of the buffer layer is coplanar with respective upper surfaces of the first and the second semiconductor chips in a space between the first and the second semiconductor chips.

13. The semiconductor package of claim 1, wherein the encapsulant does not overlap the buffer layer in a vertical direction in a space between the first and the second semiconductor chips.

14. The semiconductor package of claim 1,
wherein the interposer further comprises a semiconductor substrate and an interconnection structure on the semiconductor substrate, and
wherein the first and the second semiconductor chips are connected to each other through the interconnection structure.

15. A semiconductor package comprising:
a substrate;
a chip structure on the substrate, the chip structure comprising a semiconductor chip connected to the substrate and an underfill portion sealing at least a portion of a space between the substrate and the semiconductor chip;
a dam structure on an upper surface of the substrate, wherein the dam structure is arranged along at least a portion of a circumference of the underfill portion;
a buffer layer, wherein the buffer layer seals the underfill portion and at least a portion of a side surface of the semiconductor chip; and
an encapsulant on the substrate, wherein the encapsulant seals the buffer layer,
wherein the buffer layer comprises a material having an elastic modulus lower than an elastic modulus of the underfill portion and an elastic modulus of the encapsulant.

16. The semiconductor package of claim 15, wherein the semiconductor chip comprises a lower semiconductor chip and an upper semiconductor chip on the lower semiconductor chip.

17. The semiconductor package of claim 16,
wherein the chip structure further comprises an encapsulating member surrounding the upper semiconductor chip, and
wherein the buffer layer is in contact with the encapsulating member.

18. A semiconductor package comprising:
a package substrate;
an interposer on the package substrate;
a first semiconductor chip and a second semiconductor chip, wherein the first and the second semiconductor chips are spaced apart from each other on the interposer;
an underfill portion between the interposer and each of the first and the second semiconductor chips;
a dam structure on the interposer and surrounding the underfill portion;
a buffer layer on the interposer and covering at least a portion of respective side surfaces of the underfill portion and the first and the second semiconductor chips; and
an encapsulant on the interposer and covering side surfaces of the buffer layer,
wherein the dam structure comprises an inner side surface in contact with the underfill portion and an outer side surface in contact with the buffer layer.

19. The semiconductor package of claim 18, wherein a top end of the buffer layer is lower than a top end of the first and the second semiconductor chips.

20. The semiconductor package of claim 18, wherein the encapsulant is in contact with at least a portion of respective side surfaces of the first and the second semiconductor chips.
